(19) United States
(12) Patent Application Publication
(10) Pub. No.: US 2014/0327118 A1
(43) Pub. Date: Nov. 6, 2014

(54) POWER SEMICONDUCTOR DEVICE AND FABRICATING METHOD THEREOF

(71) Applicant: MOSEL VITELIC INC., Hsinchu (TW)

(72) Inventors: Chien-Ping Chang, Hsinchu (TW); Chien-Chung Chu, Hsinchu (TW)

(73) Assignee: MOSEL VITELIC INC., Hsinchu (TW)

(21) Appl. No.: 13/966,472

(22) Filed: Aug. 14, 2013

(30) Foreign Application Priority Data
May 6, 2013 (TW) 102116076

(51) Int. Cl. H01L 21/02; H01L 29/06; H01L 29/66

(52) U.S. Cl. CPC H01L 21/02664; H01L 29/66333; H01L 29/66712; H01L 29/0688; H01L 21/02617
USPC 257/653; 438/494; 438/135; 438/268

(57) ABSTRACT

A method of fabricating a power semiconductor device includes the following steps. Firstly, a substrate is provided. A first epitaxial layer is formed over the substrate. A first trench is formed in the first epitaxial layer. A second epitaxial layer is refilled into the first trench. The first epitaxial layer and the second epitaxial layer are collaboratively defined as a first semiconductor layer. A third epitaxial layer is formed over the substrate, and a second trench is formed in the third epitaxial layer. A first doping region is formed in a sidewall of the second trench. An insulation layer is refilled into the second trench. The insulation layer, the first doping region and the third epitaxial layer are collaboratively defined as a second semiconductor layer. The power semiconductor device fabricated by the fabricating method can withstand high voltage and has low on-resistance.

### FIELD OF THE INVENTION

The present invention relates to a semiconductor device and a fabricating method thereof, and more particularly to a power semiconductor device and a fabricating method thereof.

### BACKGROUND OF THE INVENTION

Recently, high-power semiconductor devices such as vertical double-diffused metal oxide semiconductors (VDMOS), isolated gate bipolar transistors (IGBT) or diodes are widely used as many electronic components such as power supply switches, motor control components, telecommunication switches, factory automation components, electronic automation components, high-speed power switches, or the like.

As known, the reduction of the resistance of the drift region is an easy way to produce a vertical high-power semiconductor device with high breakdown voltage and low on-resistance. Generally, for reducing the resistance of the drift region, the withstand voltage of the drift region of the high-power semiconductor device should be firstly increased. The deep trench with a depth larger than 40 μm is usually used as an epi-refill structure or an insulated material refill structure in order to increase the withstand voltage and reducing the resistance.

FIGS. 1A˜1D are schematic cross-sectional views illustrating a method of forming a drift region of a conventional power semiconductor device. Firstly, as shown in FIG. 1A, a first epitaxial layer 11 with a thickness of about 40 μm is formed on a substrate 10. Then, as shown in FIG. 1B, plural trenches 12 with a depth of about 40 μm are formed in the first epitaxial layer 11. Then, as shown in FIG. 1C, a second epitaxial layer 13 is refilled into the trenches 12 and formed over the top surface of the first epitaxial layer 11. Consequently, a pn junction is formed between the first epitaxial layer 11 and the second epitaxial layer 13. Then, as shown in FIG. 1D, a surface planarization process is performed to remove the part of the second epitaxial layer 13 over the top surface of the first epitaxial layer 11, thereby exposing the first epitaxial layer 11.

Then, an ion implantation process and a drive-in process are performed to form a body region, and a gate oxide layer and a polysilicon gate are sequentially formed over the above structures. Then, another ion implantation process and another drive-in process are performed to form an N+ source region in the body region. Then, a chemical vapor deposition (CVD) process is performed to deposit a dielectric film (e.g. borophosphosilicate glass, BPSG) on the polysilicon gate, and a source contact window is formed in the body region and the N+ source region. Afterwards, a front-side metal layer and a back-side metal layer are deposited as a source metal layer and a drain metal layer, respectively. Meanwhile, the fabrication of the power semiconductor is completed.

FIGS. 2A˜2D are schematic cross-sectional views illustrating a method of forming a drift region of another conventional power semiconductor device. Firstly, as shown in FIG. 2A, an epitaxial layer 21 with a thickness of about 40 μm is formed on a substrate 20. Then, as shown in FIG. 2B, a photolithography and etching process is performed to form a photoresist layer 22 on the epitaxial layer 21, and plural trenches 23 with a depth of about 40 μm are formed in the epitaxial layer 21. Then, as shown in FIG. 2C, an ion implantation process and a drive-in process are performed to form a diffusion layer 24 in the sidewall of the epitaxial layer 21, and thus a pn junction is formed between the epitaxial layer 21 and the diffusion layer 24. Then, the photoresist layer 22 is removed. Then, as shown in FIG. 2D, an insulated material 25 (e.g. an oxide layer) is refilled into the trenches 23 and formed over the top surfaces of the epitaxial layer 21 and the diffusion layer 24. Then, a surface planarization process is performed to remove the part of the insulated material 25 over the top surfaces of the epitaxial layer 21 and the diffusion layer 24. The subsequent processes are similar to those as mentioned above, and are not redundantly described herein.

However, the above methods of fabricating the conventional power semiconductor device still have some drawbacks. For example, for forming the drift region with pn junction charge equilibrium, the process of forming the trenches (>40 μm) and the epi-refilling process or the insulated material refilling process (see FIGS. 1B˜1C and FIGS. 2B˜2D) are very complicated. Moreover, since the trenches 12 and 23 are relatively deep, it is difficult to control the formation of these structures. Moreover, since the aspect ratios of the trenches 12 and 23 are very large, voids are readily generated during the epi-refilling process or the insulated material refilling process. Under this circumstance, the device fails to withstand higher voltage, and the quality of the high-power semiconductor device is adversely affected.

### SUMMARY OF THE INVENTION

The present invention provides a fabricating method of a power semiconductor device in order to simplify the process of forming the trenches and reduce the possibility of generating voids during the epi-refilling process or the insulated material refilling process.

The present invention also provides a power semiconductor device with increased withstand voltage and reduced on-resistance.

In accordance with an aspect of the present invention, there is provided a method of fabricating a power semiconductor device. The method includes the following steps. Firstly, a substrate is provided. A first epitaxial layer is formed over the substrate. A first trench is formed in the first epitaxial layer. A second epitaxial layer is refilled into the first trench. The first epitaxial layer and the second epitaxial layer are collaboratively defined as a first semiconductor layer. A third epitaxial layer is formed over the substrate, and a second trench is formed in the third epitaxial layer. A first doping region is formed in a sidewall of the second trench. An insulation layer is refilled into the second trench. The insulation layer, the first doping region and the third epitaxial layer are collaboratively defined as a second semiconductor layer.

In accordance with another aspect of the present invention, there is provided a power semiconductor device. The power semiconductor device includes a substrate, a first semiconductor layer, and a second semiconductor layer. The first semiconductor layer is disposed over the substrate, and includes a first epitaxial layer and a second epitaxial layer. A first trench is formed in the first epitaxial layer, and the second epitaxial layer is disposed within the first trench. The second semiconductor layer is disposed over the substrate, and includes a third epitaxial layer, a first doping region and an insulation layer. A second trench is formed in the third epitaxial layer, the first doping region is formed in a sidewall of the second trench, and the insulation layer is disposed within the second trench.

The above contents of the present invention will become more readily apparent to those ordinarily skilled in the art after reviewing the following detailed description and accompanying drawings, in which:

### BRIEF DESCRIPTION OF THE DRAWINGS

FIGS. 1A˜1D are schematic cross-sectional views illustrating a method of forming a drift region of a conventional power semiconductor device;

FIGS. 2A˜2D are schematic cross-sectional views illustrating a method of forming a drift region of another conventional power semiconductor device;

FIGS. 3A˜3I are schematic cross-sectional views illustrating a method of fabricating a power semiconductor device according to an embodiment of the present invention;

FIG. 4 is a schematic cross-sectional view illustrating a power semiconductor device produced by the fabricating method of the present invention; and

FIG. 5 is a schematic cross-sectional view illustrating another power semiconductor device produced by the fabricating method of the present invention.

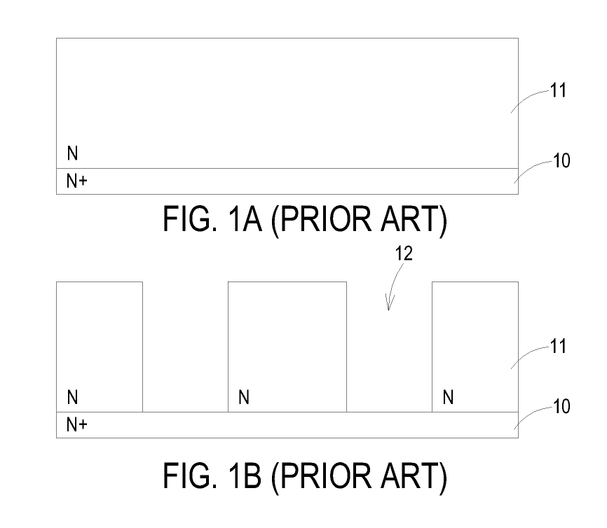

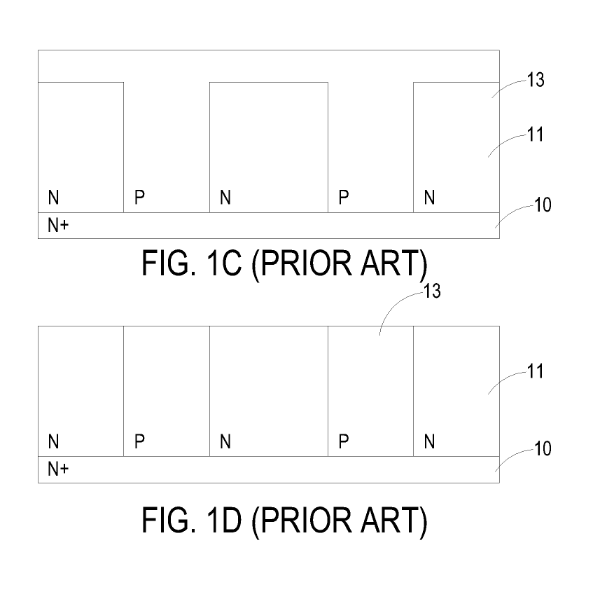

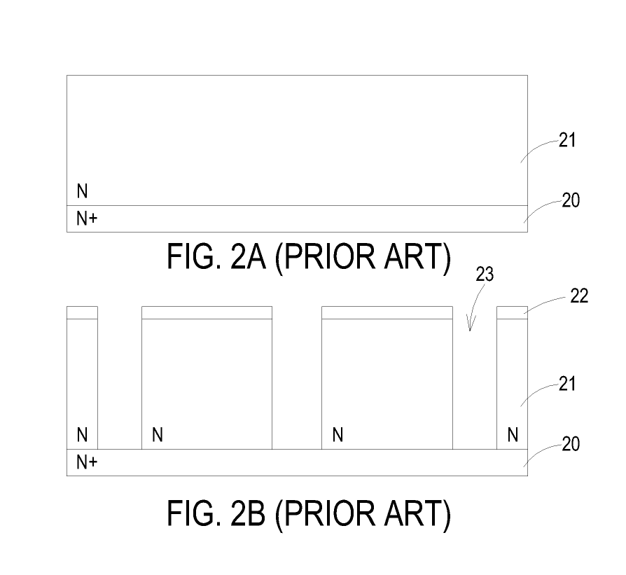

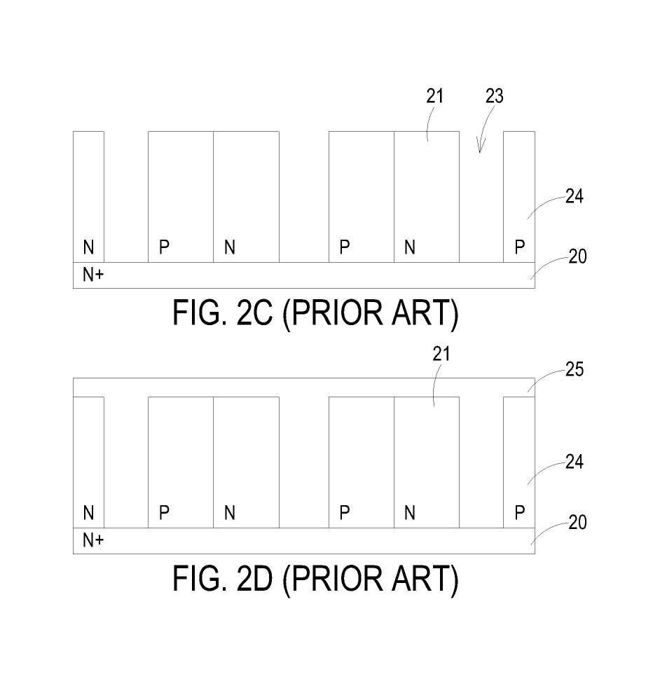

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

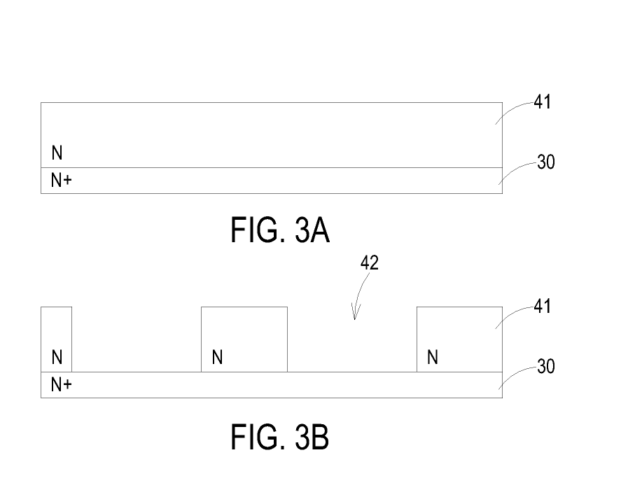

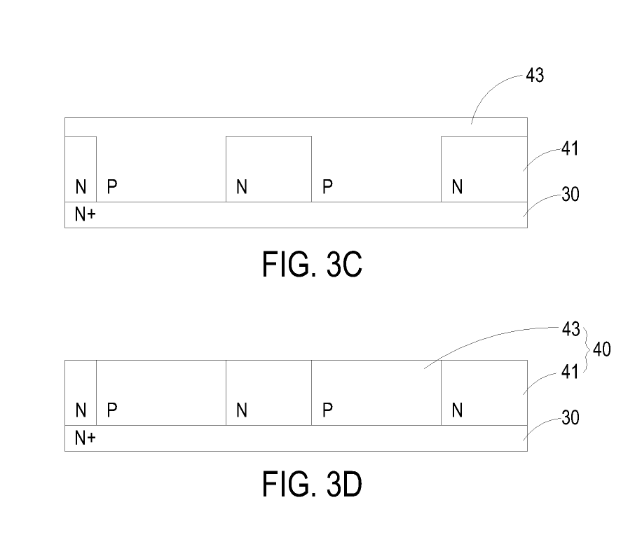

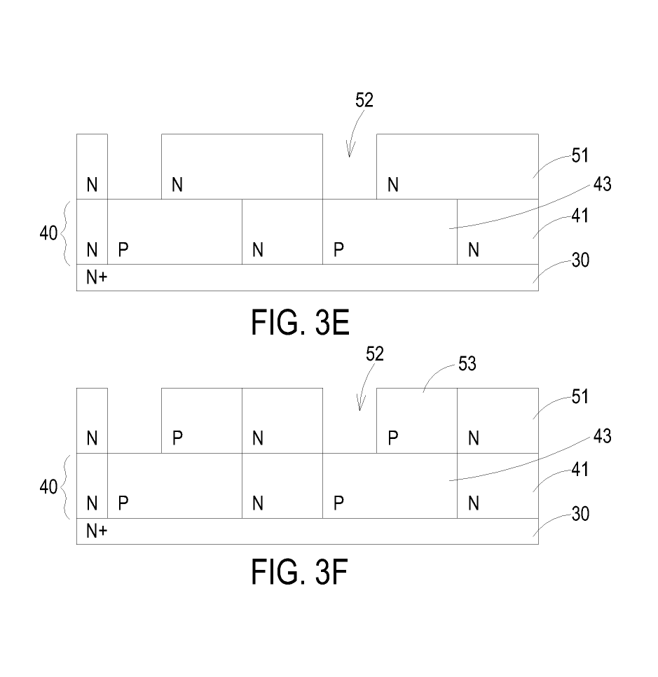

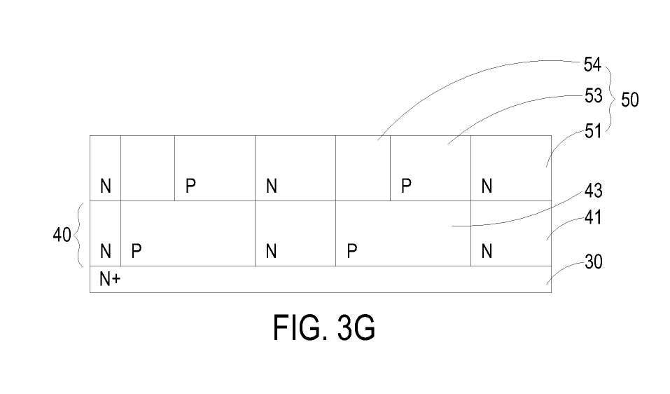

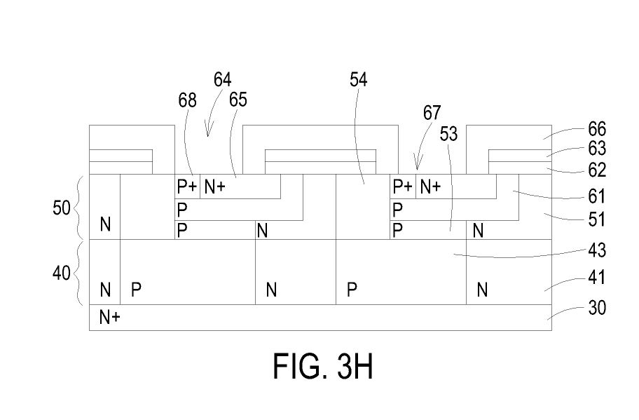

FIGS. 3A˜3I are schematic cross-sectional views illustrating a method of fabricating a power semiconductor device according to an embodiment of the present invention. Firstly, as shown in FIG. 3A, a substrate 30 is provided, and a first epitaxial layer 41 is formed on the substrate 30 by epitaxial growth. In this embodiment, the substrate 30 is a silicon substrate. Moreover, both of the substrate 30 and the first epitaxial layer 41 have a first polarity (e.g. N type). The thickness of the first epitaxial layer 41 is about 20 μm, but is not limited thereto.

Then, as shown in FIG. 3B, a photolithography and etching process is performed. Consequently, a photoresist layer (not shown) with a trench pattern is formed over the first epitaxial layer 41. Then, by an etching process, the part of the first epitaxial layer 41 uncovered by the trench pattern of the photoresist layer is removed until a surface of the substrate 30 is exposed. Consequently, plural first trenches 42 are formed in the first epitaxial layer 41. The depth of the first trench 42 is substantially equal to the thickness of the first epitaxial layer 41 (i.e. about 20 μm).

Then, as shown in FIG. 3C, a second epitaxial layer 43 is refilled into the first trenches 42. The second epitaxial layer 43 has a second polarity (e.g. P type).

Then, as shown in FIG. 3D, a surface planarization process is performed to remove the part of the second epitaxial layer 43 over the top surface of the first epitaxial layer 41, thereby exposing the first epitaxial layer 41. The first epitaxial layer 41 and the second epitaxial layer 43 are collaboratively defined as a first semiconductor layer 40. Moreover, a pn junction is formed between the first epitaxial layer 41 and the second epitaxial layer 43.

After the first semiconductor layer 40 is formed, a third epitaxial layer 51 is formed over the first semiconductor layer 40 by epitaxial growth. The third epitaxial layer 51 has the first polarity (e.g. N type). The thickness of the third epitaxial layer 51 is substantially identical to the thickness of the first epitaxial layer 41, but is not limited thereto. Then, by a second etching process, plural second trenches 52 are formed in the third epitaxial layer 51. The positions of the second trenches 52 are over the second epitaxial layer 43.

Then, as shown in FIG. 3F, an ion implantation process is performed to implant a dopant with the second polarity (e.g. P type) into the sidewalls of the second trenches 52, so that a first doping region 53 is formed in the third epitaxial layer 51.

Then, as shown in FIG. 3G, an insulation layer 54 (e.g. an oxide material) is refilled into the second trenches 52, and a second surface planarization process is performed to remove the part of the insulation layer 54 over the top surfaces of the third epitaxial layer 51 and the first doping region 53, thereby exposing the third epitaxial layer 51 and the first doping region 53. Meanwhile, a second semiconductor layer 50 is produced. The second semiconductor layer 50 is defined by the third epitaxial layer 51, the first doping region 53 and the insulation layer 54 collaboratively. Moreover, a pn junction is formed between the third epitaxial layer 51 and the first doping region 53. The positions of the third epitaxial layer 51 and the first doping region 53 are over the second epitaxial layer 43.

Next, please refer to FIG. 3H. After the first semiconductor layer 40 and the second semiconductor layer 50 are produced, a drive-in process is performed to implant a dopant with the second polarity (e.g. P type) into the second semiconductor layer 50, so that a body region 61 is formed in the third epitaxial layer 51 and the first doping region 53 of the second semiconductor layer 50. Then, a thin gate oxide layer 62 is deposited on the second semiconductor layer 50. Then, a layer of polysilicon material is deposited on the gate oxide layer 62, and a polysilicon material is heavily doped as a polysilicon layer 63, which will be served as a gate electrode of the power semiconductor device. After a part of the gate oxide layer 62 and a part of the polysilicon layer 63 are removed, a part of the surface of the second semiconductor layer 50 is exposed. Consequently, plural third trenches 64 are formed. The third trenches 64 are aligned with the body region 61. Then, a drive-in process is performed to implant a high-concentration dopant with the first polarity (e.g. N type) into the body region 61 of the second semiconductor layer 50, so that a second doping region 65 is formed in the body region 61. Then, a passivation layer 66 is formed on the surfaces of the third trench 64 and the polysilicon layer 63. For example, the passivation layer 66 is a borophosphosilicate glass (BPSG) or an inter-layer dielectric (ILD) layer for protecting the polysilicon layer 63. Then, a photolithography and etching process is performed to remove a part of the passivation layer 66 on a bottom of the third trench 64, so that a part of the surface of the second semiconductor layer 50 is exposed. Meanwhile, a contact window 67 is defined. After the above steps are performed, an ion implantation process is performed to implant a dopant with the second polarity (e.g. P type) into the second doping region 65, so that a third doping region 68 is formed in the second doping region 65.

Then, as shown in FIG. 3I, a source metal layer 69 is deposited on the surface of the passivation layer 66 and the exposed surface of the second semiconductor layer 50, and a shielding layer (not shown) is deposited on the source metal layer 69 for protection. Afterwards, the bottom surface of the substrate 30 is polished, and a back-side metal layer is deposited on the bottom surface of the substrate 30, so that a drain metal layer 70 is formed on the back side of the substrate 30. Meanwhile, the fabrication of the power semiconductor device is completed. In accordance with the present invention, the power semiconductor device is a vertical double-diffused metal oxide semiconductor (VDMOS), an isolated gate bipolar transistor (IGBT), a diode or a thyristor, but is not limited thereto.

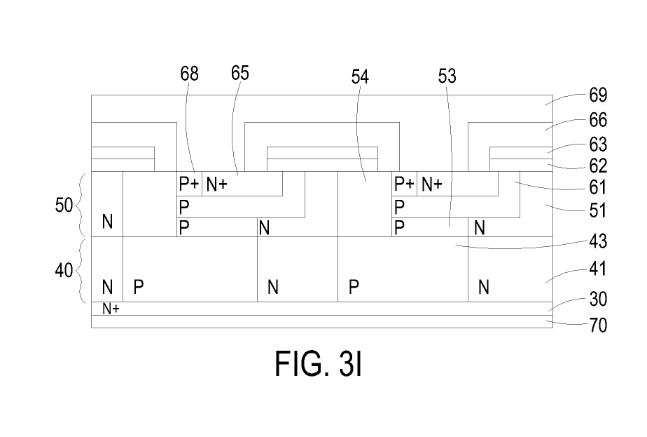

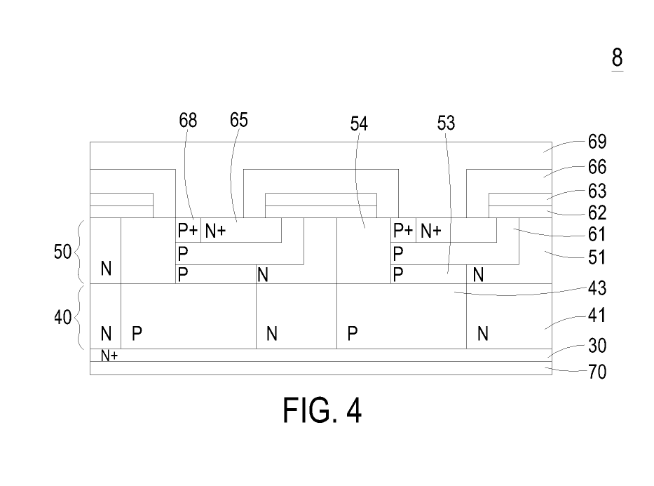

FIG. 4 is a schematic cross-sectional view illustrating a power semiconductor device produced by the fabricating method of the present invention. In this embodiment, the power semiconductor device 8 is a high-voltage power semiconductor device such as an N-channel vertical double-diffused metal oxide semiconductor (N-channel VDMOS). Hereinafter, the structure of the power semiconductor device 8 produced by the fabricating method of the present invention will be illustrated in more details with reference to FIG. 4. As shown in FIG. 4, the power semiconductor device 8 comprises a substrate 30, a first semiconductor layer 40, a second semiconductor layer 50, a polysilicon layer 63 (i.e. the gate electrode), a source metal layer 69, and a drain metal layer 70. The first semiconductor layer 40 is formed on the substrate 30. In addition, the first semiconductor layer 40 comprises a first epitaxial layer 41 and a second epitaxial layer 43. Each of the first epitaxial layer 41 and the second epitaxial layer 43 has a thickness of about 20 μm. A first trench 42 is formed in the first epitaxial layer 41. The second epitaxial layer 43 is disposed within the first trench 42. Moreover, the first epitaxial layer 41 and the second epitaxial layer 43 are collaboratively defined as the first semiconductor layer 40. Moreover, a pn junction is formed between the first epitaxial layer 41 and the second epitaxial layer 43. The second semiconductor layer 50 comprises a third epitaxial layer 51, a first doping region 53 and an insulation layer 54. The third epitaxial layer 51 is formed on the first semiconductor layer 40. Moreover, the third epitaxial layer 51 has a thickness of about 20 μm. A second trench 52 is formed in the third epitaxial layer 51. The first doping region 53 is formed in a sidewall of the second trench 52. The insulation layer 54 is disposed within the second trench 52. Moreover, the third epitaxial layer 51, the first doping region 53 and the insulation layer 54 are collaboratively defined as the second semiconductor layer 50. Moreover, a pn junction is formed between the third epitaxial layer 51 and the first doping region 53. The positions of the third epitaxial layer 51 and the first doping region 53 are over the second epitaxial layer 43.

Please refer to FIG. 4 again. The second semiconductor layer 50 of the power semiconductor device 8 further comprises a body region 61, a heavily-doped second doping region 65 and a third doping region 68. The body region 61 is formed in the third epitaxial layer 51 and the first doping region 53 of the second semiconductor layer 50. Moreover, a gate oxide layer 62, a polysilicon layer 63 and a passivation layer 66 are sequentially formed on the second semiconductor layer 50. Moreover, the passivation layer 66 and a third trench 64 are covered with a source metal layer 69. A drain metal layer 70 is formed on a back side of the substrate 30. The other components are similar to those mentioned above, and are not redundantly described herein.

From the above discussions, the present invention uses a multi-stage process of forming the trenches to replace the conventional single-stage of forming the deep trenches. Consequently, the power semiconductor device 8 has increased withstand voltage and reduced on-resistance. In this embodiment, the first trench 42 with the depth of about 20 μm is formed in a first stage. After an epi-refilling process is performed, the first semiconductor layer 40 is produced. The second trench 52 with the depth of about 20 μm is formed in a second stage. After a dopant is implanted into a sidewall of the second trench 52 and an insulation layer 54 is refilled into the second trench 52, the second semiconductor layer 50 is produced. Consequently, the combination of the first semiconductor layer 40 and the second semiconductor layer 50 can result in a 40 μm-semiconductor drift region (see FIG. 3G). Since the trenches are formed in several stages according to the present invention, the depths of the first trench 42 and the second trench 52 are shallower than the conventional trench. In other words, these trenches can be easily controlled by the fabricating method of the present invention. Moreover, since the aspect ratios of the first trench 42 and the second trench 52 are reduced, the epi-refilling process in the first stage and the ion implantation process and the insulation layer refilling process in the second stage are more easily when compared with the formation of the conventional trench. Consequently, the problem of causing voids during the process of refilling the deep trench by the conventional fabricating method will be minimized. Under this circumstance, the withstand voltage and the reliability of the power semiconductor device will be increased, and the quality of the power semiconductor device will be enhanced.

It is noted that numerous modifications and alterations of the may be made while retaining the teachings of the invention. For example, the first stage and the second stage of forming the drift region of the power semiconductor device may be exchanged. That is, after the second semiconductor layer 50 is formed on the substrate 30, the first semiconductor layer 40 is formed on the second semiconductor layer 50. Moreover, the drift region of the power semiconductor device is not restricted to the two-layered structure. That is, the drift region of the power semiconductor device drift region of the power semiconductor device may be composed of three semiconductor layers, four semiconductor layers or more semiconductor layers.

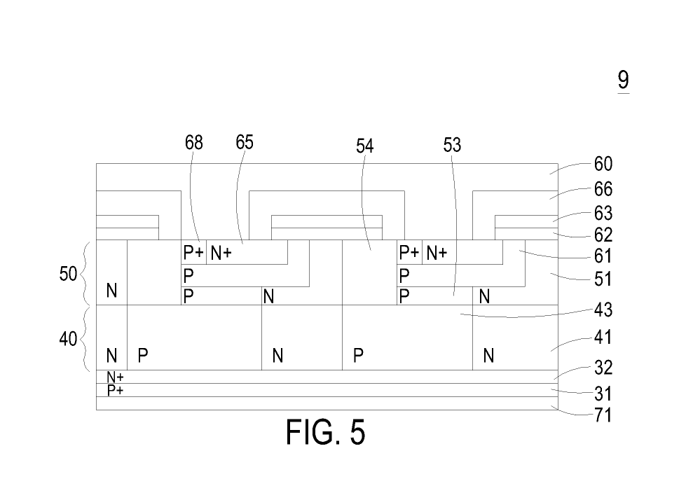

FIG. 5 is a schematic cross-sectional view illustrating another power semiconductor device produced by the fabricating method of the present invention. In this embodiment, the power semiconductor device 9 is a high-voltage power semiconductor device such as an N-channel isolated gate bipolar transistor (N-channel IGBT). The structure and the fabricating method of the power semiconductor device 9 are similar to those described in FIGS. 3A-3I and FIG. 4. Component parts and elements corresponding to those of FIG. 4 are designated by identical numeral references, and detailed description thereof is omitted. In comparison with the fabricating method of FIGS. 3A-3I and the power semiconductor device 8 of FIG. 4, the substrate 31 of the power semiconductor device 9 has a second polarity (e.g. P type). Moreover, a buffer layer 32 is formed on the substrate 31, and the first epitaxial layer 41 is formed on the buffer layer 32. The buffer layer 32 has the first polarity (e.g. N type). Moreover, in the power semiconductor device 9, an emitter metal layer 60 is deposited on the surface of the passivation layer 66 and the exposed surface of the second semiconductor layer 50, and a shielding layer (not shown) is deposited on the emitter metal layer 60 for protection. Moreover, after the bottom surface of the substrate 31 of the power semiconductor device 9 is polished, a back-side metal layer is deposited on the bottom surface of the substrate 31, so that a collector metal layer 71 is formed on the back side of the substrate 31.

In this embodiment, the power semiconductor device 9 principally comprises the substrate 31, the buffer layer 32, the first semiconductor layer 40 and the second semiconductor layer 50. Each of the first semiconductor layer 40 and the second semiconductor layer 50 has a thickness of about 20 μm. Moreover, the power semiconductor device 9 further comprises the polysilicon layer 63 (i.e. the gate electrode), the emitter metal layer 60 and the collector metal layer 71. The forming processes and the structures of these components are similar to those mentioned above, and are not redundantly described herein.

From the above descriptions, the present invention uses a multi-stage process of forming the trenches to replace the conventional single-stage of forming the deep trenches. Moreover, according to the fabricating method of the present invention, the aspect ratios of the trenches are reduced. Consequently, the process of forming the trenches will be simplified and the problem of causing voids during the epi-refilling process or the insulated material refilling process will be overcome. In other words, the complexity of fabricating the power semiconductor device is largely reduced, and the power semiconductor device has increased withstand voltage and reduced on-resistance. Moreover, by the fabricating method of the present invention, the yield of the power semiconductor device is increased, and the fabricating cost is reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of fabricating a power semiconductor device, said method comprising steps:
(a) providing a substrate;
(b) forming a first epitaxial layer over said substrate;
(c) forming a first trench in said first epitaxial layer;
(d) refilling a second epitaxial layer into said first trench, wherein said first epitaxial layer and said second epitaxial layer are collaboratively defined as a first semiconductor layer;
(e) forming a third epitaxial layer over said substrate, and forming a second trench in said third epitaxial layer;
(f) forming a first doping region in a sidewall of said second trench; and
(g) refilling an insulation layer into said second trench, wherein said insulation layer, said first doping region and said third epitaxial layer are collaboratively defined as a second semiconductor layer.

2. The method according to claim 1, wherein each of said first epitaxial layer and said second epitaxial layer has a thickness of 20 μm.

3. The method according to claim 1, wherein a pn junction is formed between said first epitaxial layer and said second epitaxial layer, and another pn junction is formed between said third epitaxial layer and said first doping region.

4. The method according to claim 1, wherein said third epitaxial layer of said second semiconductor layer is formed over said first semiconductor layer.

5. The method according to claim 4, wherein said second trench is disposed over said second epitaxial layer, and said first doping region and said insulation layer are disposed over said second epitaxial layer.

6. The method according to claim 4, wherein said step (b) comprises sub-steps of:
(b1) forming a buffer layer on said substrate; and
(b2) forming said first epitaxial layer on said buffer layer.

7. The method according to claim 6, wherein after said step (g), said method further comprises steps of:
(h) forming a body region in said third epitaxial layer and said first doping region;
(i) forming a polysilicon layer over said second semiconductor layer;
(j) forming an emitter metal layer over said polysilicon layer; and
(k) forming a collector metal layer on said substrate.

8. The method according to claim 4, wherein after said step (g), said method further comprises steps of:
(h) forming a body region in said third epitaxial layer and said first doping region;
(i) forming a polysilicon layer over said second semiconductor layer;
(j) forming a source metal layer over said polysilicon layer; and
(k) forming a drain metal layer on said substrate.

9. The method according to claim 8, wherein said step (i) comprises sub-steps of:
(i1) forming a gate oxide layer over said second semiconductor layer; and
(i2) forming said polysilicon layer over said gate oxide layer.

10. The method according to claim 9, wherein between said step (i) and said step (j), said method further comprises steps of:
(l1) removing a part of said gate oxide and a part of said polysilicon layer to expose a part of said second semiconductor layer, thereby defining a third trench;
(l2) forming a second doping region in said body region;
(l3) forming a passivation layer in said third trench and over said polysilicon layer and removing a part of said passivation layer on a bottom of said third trench, thereby defining a contact window; and
(l4) forming a third doping region in said second doping region.

11. The method according to claim 1, wherein said power semiconductor device is a vertical double-diffused metal oxide semiconductor (VDMOS), an isolated gate bipolar transistor (IGBT), a diode or a thyristor.

12. A power semiconductor device, comprising:
a substrate;
a first semiconductor layer disposed over said substrate, and comprising a first epitaxial layer and a second epitaxial layer, wherein a first trench is formed in said first epitaxial layer, and said second epitaxial layer is disposed within said first trench; and
a second semiconductor layer disposed over said substrate, and comprising a third epitaxial layer, a first doping region and an insulation layer, wherein a second trench is formed in said third epitaxial layer, said first doping region is formed in a sidewall of said second trench, and said insulation layer is disposed within said second trench.
